(19) United States
(12) Patent Application Publication
(10) Pub. No.: US 2004/0089885 A1
(43) Pub. Date: May 13, 2004

(54) Layout techniques for the creation of dense radiation tolerant MOSFETs with small width-length ratios

(76) Inventors: Mark N. Martin, Columbia, MD (US); Kim Strohbehn, Ellicott City, MD (US); Martin E. Fraeman, Olney, MD (US)

Correspondence Address: THE JOHNS HOPKINS UNIVERSITY, Applied Physics Laboratory, 11100 Johns Hopkins Road, Laurel, MD, 20723-6099, US

(21) Appl. No.: 10/659,479

(22) Filed: Sep. 10, 2003

Related U.S. Application Data
(60) Provisional application No. 60/409,819, filed on Sep. 10, 2002.

(51) Int. Cl. H01L 29/80

(52) U.S. Cl. 257/262

(57) ABSTRACT

A metal oxide semiconductor field effect transistor (“MOSFET”) layout with small width-length ratio allows for greater flexibility in design and density in dimension than the conventional annular technique is provided. Accordingly, higher density MOSFET of this layout gives more devices on a single semiconductor wafer. An additional benefit of this layout is a reduced current density at the enclosed terminal wherein there is less localized heating and damages of materials composing the transistor.

### CROSS-REFERENCE TO RELATED APPLICATIONS

This application claims the benefit of U.S. Provisional Application No. 60/409,819 filed Sep. 10, 2002, the contents of which are incorporated herein by reference.

### BACKGROUND OF THE INVENTION

1. Field of the Invention

The present invention generally relates to a method for fabricating a semiconductor device having Metal Oxide Semiconductor Field Effect Transistor (“MOSFET”), and is particularly suitable for fabricating a dense radiation tolerant MOSFET with small width-length ratio.

2. Description of the Related Art

As the number and density of devices being formed on an integrated circuit (“IC”) increases, the scaling-down of IC dimensions becomes critical. Smaller dimensions are required for reduced area capacitance and higher yield in IC fabrication.

FIG. 1 shows a transistor 10 that includes a drain 12, a source 16 separated from the drain 12, a dielectric layer 14 between the drain 12 and the source 16, and a gate electrode 18.

FIG. 1A shows a transistor 20 that is formed according to a conventional annular technique implemented by stretching a segment X-X′ 40 (FIG. 1) around a drain 12 along the path signified by the dotted line. Thus, the annular transistor 20 includes a drain 12, a source 16 separated from and concentric with the drain 12 and having an annular shape, a dielectric layer 14 having an annular shape located between the drain 12 and the source 16, and a gate electrode 18.

The drain 12 of the annular transistor 20 is surrounded by the dielectric layer 14. In this configuration, the drain 12, dielectric layer 14 and source 16 may be circular, rectangular or other geometric configuration.

In general, a width-length ratio of a transistor is defined as follows: a length equal to the distance of the dielectric layer 14 between the drain 12 and source 16. A width is also defined as the mean width of the dielectric layer 14 orthogonal to the current flow at both the drain 12 and source 16.

FIG. 1B shows a transistor 30 that includes a drain 12, a source 16 separated from and concentric with the drain 12 and having an annular shape, a dielectric layer 14 having an annular shape located between the drain 12 and the source 16, and a gate electrode 18.

In applications where it is desirable to have long channel lengths, transistor area increases as the square of the length of the transistor, thereby transforming the geometry of the transistor as shown from the transistor 20 (FIG. 1A) to the transistor 30 (FIG. 1B). In this transformation, the length and width of transistor 30 are not independent factors in the conventional annular technique.

In the conventional annular transistor, a width-length ratio (W/L ratio) has a theoretical lower limit of only 4, while this assumes an infinitely long gate. For example, to achieve an effective W/L ratio of 5 using the conventional annular technique, the channel length must be 12 units long. The resulting transistor has an overall area of approximately 3600 square units. The length and width of the transistor are not independent factors in the conventional transistor design.

An additional disadvantage of conventional techniques is an increased current density at the enclosed terminal. The large W/L ratio of conventional techniques results in high current density at the enclosed terminal. Higher current density is undesirable because it can lead to localized heating and damage to materials composing the transistor and other effects that all lead to reduced lifetime of the transistor.

It would therefore be desirable to provide a greater flexibility in design and density in the dimension of annular transistors and techniques for their manufacturing.

### SUMMARY OF THE INVENTION

It is, therefore, an object of the present invention to provide a method for fabricating a Metal Oxide Semiconductor Field Effect Transistor (“MOSFET”) with small width-length ratios wherein the width and length are independently adjusted.

It is a further object of the present invention to provide the MOSFET layout, which allows for greater flexibility in design and greater density in dimension of a transistor over its conventional counterpart.

In keeping with these and other objects of the present invention, a method for fabricating a metal oxide semiconductor field effect transistor (MOSFET) comprising the steps of:

providing a substrate having spaced apart source and drain regions thereon with the space between the source and drain regions defining a channel region;

forming a dielectric layer peripherally about the drain portion to completely surround the drain region and in contact with the source region to fill the channel region, wherein the area of the dielectric layer in the channel region between the drain and source regions is variable in length; and,

forming a gate electrode layer on at least a portion of the dielectric layer in the channel region.

Furthermore, a device for a MOSFET having a substrate, is also provided comprising:

spaced apart source and drain regions on the substrate with the space between the source and drain regions defining a channel region;

a dielectric layer peripherally about the drain region to completely surround the drain region and filling the channel region such that the dielectric layer is in contact with the source region, wherein the area of the dielectric layer in the channel region between the drain and source regions is variable in length; and,

a gate electrode layer covering at least a portion of the dielectric layer in the channel region.

### BRIEF DESCRIPTION OF THE DRAWINGS

The above and other objects, features and advantages of the present invention will become more apparent from the following detailed description when taken in conjunction with the accompanying drawings, in which:

FIG. 1 is a plan view of transistor indicating a segment X-X′ for stretching;

FIG. 1A is a plan view of conventional annular transistor;

FIG. 1B is a plan view of conventional annular transistor which is transformed from FIG. 1A;

FIG. 2 is a plan view of transistor indicating a segment Y-Y′ for stretching;

FIG. 2A is a plan view of one embodiment of enclosed layout transistor according to the present invention;

FIG. 2B is a plan view of another embodiment of enclosed layout transistor according to the present invention which is transformed from FIG. 2A; and,

FIG. 3 is a cross section through one leg of enclosed layout transistor according to the present invention.

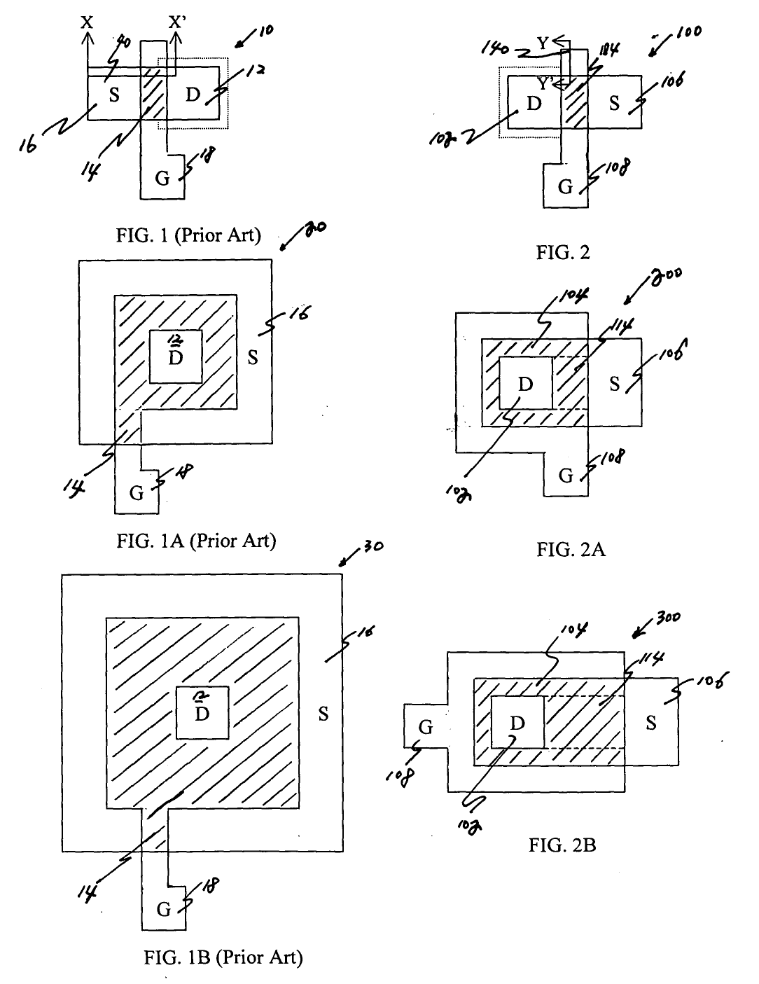

### DETAILED DESCRIPTION OF THE PREFERRED EMBODIMENTS

A preferred embodiment of the present invention will be described herein below with reference to the accompanying drawings. In the following description, well-known functions or constructions are not described in detail since they would obscure the invention in unnecessary detail.

The preferred embodiments of the present invention provide a layout and method for forming Metal Oxide Semiconductor Field Effect Transistor (“MOSFET”) with a small width-length ratio.

FIG. 2 shows a transistor 100 that includes a drain 102, a source 106 separated from the drain 102, a dielectric layer 104 between the drain 102 and the source 106, and a gate electrode 108. The drain 102 and source 104 are determined by the relative voltage of terminals of the transistor and are interchangeable.

FIG. 2A is a plan view of enclosed layout transistor 200 in accordance with an illustrative, but non-limiting, embodiment of the present invention. With regard to FIG. 2A, transistor 200 according to the present invention is implemented by stretching the segment Y-Y′ 140 (FIG. 2) around the drain 102 along the path signified by the dotted line. The geometry of the transistor 200 is transformed from the transistor 100 (FIG. 2) according to the present invention. Thus, a channel region 114 of the dielectric layer 104 between drain 102 and source 106 is variable in length with independent adjustment of width and length of the transistor 200.

FIG. 2A shows the transistor 200 that may be formed on a substrate. The substrate can be, for example, silicon, germanium, gallium, arsenide or other presently known or later-discovered materials that are suitable for the manufacture of such semiconductor devices with mono-crystalline silicon being preferred for use herein. The individual process steps producing this configuration will be described hereinbelow. A drain region 102, source region 106 are formed on a silicon layer of the substrate to define channel region 114, which is masked and etched to define the source, drain and channel regions. The drain 102 and source 106 can be formed on any portion of the substrate, e.g., on the opposite ends of the surface of the substrate, to define channel 114 at the central portion between the source 106 and drain 102. The dielectric layer 104 is peripherally formed about the drain 102 and in channel 114 to be in contact with at least a portion of source 106. Preferably, the dielectric layer 104 completely surrounds the drain 102 circumferentially. Finally, a gate electrode layer 108 can be formed covering at least a portion of the dielectric layer 104 in the channel region 114 and preferably covers the entire surface of dielectric layer 104 in the channel region 114. Alternatively, gate electrode layer 108 can be formed peripherally about dielectric layer 104 and covering at least a portion of dielectric layer 104 in channel region 114 and preferably covering the entire surface of dielectric layer 104 in the channel region 114.

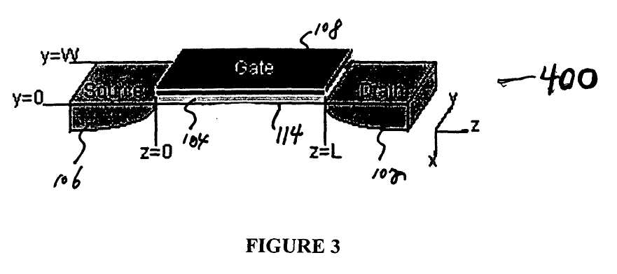

FIG. 3 shows a cross section through one leg of a device 200 (FIG. 2A) of a transistor 400 that includes a drain 102, a source 106 separated from the drain 102 and defining channel region 114, a dielectric layer 104 between the drain 102 and the source 106, and a gate electrode layer 108 disposed on the dielectric layer 104. As can be seen, at least a portion of the dielectric layer 104 of the transistor 400 is covered by the gate electrode layer 108. Preferably, gate electrode layer 108 is disposed on the entire surface of the dielectric layer 104 in the channel region 114.

Returning to FIG. 2A, the drain 102 and source 106 can be doped opposite to channel 114. The drain 102 and source 104 are determined by the relative voltage of terminals of the transistor and are interchangeable. Thus, the source 106 can be enclosed by the dielectric layer 104 like the drain 102 according to the present invention.

The dielectric layer 104 can be formed from a material such as, for example, silicon dioxide while gate electrode 108 can be formed from a material such as, for example, poly-crystalline silicon. However, as one skilled in the art would readily appreciate, other presently known or later-discovered materials possessing similar properties may be used to form dielectric layer 104 and gate electrode layer 108.

FIG. 2B shows that the geometry of transistor is transformed from the transistor 200 (FIG. 2A) to a transistor 300 while a linear increase in length results a linear increase in the device area. Thus, the resultant transistor still provides for an enclosed drain 102 but allows the width and length of the transistor 300 to be adjusted separately. The transistor 300 includes the drain 102, a dielectric layer 104 formed peripherally about the drain 102, a source 106 which is formed adjacent to the dielectric layer 104, and a gate electrode layer 108 disposed peripherally on a portion of the dielectric layer 104. The drain 102 and source 104 are determined by the relative voltage of terminals of the transistor and are interchangeable.

While the invention has been shown and described with reference to a certain preferred embodiment thereof, it will be understood by those skilled in the art that various changes in form and details may be made therein without departing from the spirit and scope of the invention as defined by the appended claims. For example, all shapes used herein can be of any geometric configuration, e.g., annular, rectangular, etc.

What is claimed is:

1. A method for fabricating a metal oxide semiconductor field effect transistor (MOSFET) comprising the steps of:
providing a substrate having spaced apart source and drain regions on the substrate with the space between the source and drain regions defining a channel region;
forming a dielectric layer peripherally about the drain portion to completely surround the drain region and in contact with the source region to fill the channel region, wherein the area of the dielectric layer in the channel region between the drain and source regions is variable in length; and,
forming a gate electrode layer on at least a portion of the dielectric layer in the channel region.

2. The method of claim 1, wherein the substrate is a layer of mono-crystalline silicon, the dielectric layer is silicon dioxide and the gate electrode layer is poly-crystalline silicon.

3. The method of claim 1, wherein a width-length ratio of the transistor is less than or equal to unity

4. The method of claim 2, wherein a width-length ratio of the transistor is less than or equal to unity.

5. The method of claim 1, wherein the source and drain regions are doped oppositely to said channel region.

6. The method of claim 1, wherein the source and drain regions are interchangeable.

7. The method of claim 1, wherein step of forming the gate electrode layer includes covering the entire portion of the dielectric layer in the channel region.

8. The method of claim 2, wherein step of forming the gate electrode layer includes covering the entire portion of the dielectric layer in the channel region.

9. The method of claim 1, wherein step of forming the gate electrode layer includes forming the gate electrode layer peripherally about the dielectric layer and covering the portion of the dielectric layer in the channel region.

10. A metal oxide semiconductor field effect transistor (MOSFET) having a substrate, comprising:
spaced apart source and drain regions on the substrate with the space between the source and drain regions defining a channel region;
a dielectric layer peripherally about the drain region to completely surround the drain region and filling the channel region such that the dielectric layer is in contact with the source region, wherein the area of the dielectric layer in the channel region between the drain and source regions is variable in length; and,
a gate electrode layer covering at least a portion of the dielectric layer in the channel region.

11. The MOSFET of claim 10, wherein the substrate is a layer of monocrystalline silicon, the dielectric layer is silicon dioxide and the gate electrode layer is polycrystalline silicon.

12. The MOSFET of claim 10, wherein a width-length ratio of the transistor is less than or equal to unity.

13. The MOSFET of claim 11, wherein a width-length ratio of the transistor is less than or equal to unity.

14. The MOSFET of claim 10, wherein the source and drain regions are doped oppositely to a channel region.

15. The MOSFET of claim 10, wherein said source and drain regions are interchangeable.

16. The MOSFET of claim 10, wherein the gate electrode layer covers the portion of the dielectric layer in the channel region.

17. The MOSFET of claim 11, wherein the gate electrode layer covers the portion of the dielectric layer in the channel region.

18. The MOSFET of claim 10, wherein the gate electrode layer is peripherally about the dielectric layer and covers the portion of the dielectric layer in the channel region.
